(19) United States
(12) Patent Application Publication
(10) Pub. No.: US 2021/0076457 A1
(43) Pub. Date: Mar. 11, 2021

(54) LIQUID HEATING DEVICE AND CLEANING SYSTEM

(71) Applicant: KELK Ltd., Kanagawa (JP)

(72) Inventor: Kazuhiro MIMURA, Kanagawa (JP)

(21) Appl. No.: 16/963,367

(22) PCT Filed: Feb. 4, 2019
(86) PCT No.: PCT/JP2019/003879

§ 371 Date: Jul. 20, 2020

(30) Foreign Application Priority Data
Feb. 28, 2018 (JP) 2018-035652

(51) Int. Cl. H05B 1/02; B08B 3/10

(52) U.S. Cl. CPC H05B 1/0244; B08B 3/10; H05B 1/0233

(57) ABSTRACT

A liquid heating device includes a circulation flow path that is connected to a branch flow path through which a first liquid supplied to an object flows, a heating device that is disposed in the circulation flow path and heats the first liquid flowing through the circulation flow path, and a cooling device that cools the first liquid flowing through the circulation flow path in a state where supply of the first liquid to the object is stopped.

### FIELD

The present invention relates to a liquid heating device and a cleaning system.

### BACKGROUND

Semiconductor devices are manufactured through a plurality of processes such as a cleaning process for cleaning a semiconductor wafer, a coating process for coating the semiconductor wafer with a photoresist, an exposure process for exposing the semiconductor wafer coated with the photoresist, and an etching process for etching the semiconductor wafer after the exposure.

In the cleaning process of the semiconductor wafer, the semiconductor wafer is cleaned with heated pure water. After being heated by a heating device, the pure water is supplied to a cleaning device that cleans the semiconductor wafer. Of the heated pure water, pure water not used for cleaning the semiconductor wafer may be returned to the heating device. By circulating the pure water not used for cleaning in a circulation flow path including the heating device, it is possible to reduce energy consumption.

### CITATION LIST

### Patent Literature

Patent Literature 1: Japanese Laid-open Patent Publication No. 2010-067636

### SUMMARY

### Technical Problem

If the heating device is restarted after being stopped, it takes time to raise the temperature to a target temperature, which results in unnecessary energy consumption. Therefore, it is preferable to maintain an operation of the heating device while circulating a liquid in the circulation flow path even if the cleaning device does not require the liquid. On the other hand, if the pure water is continuously circulated in the circulation flow path in the state where the heating device is operating, the temperature of the pure water may excessively rise.

An object in an aspect of the present invention is to maintain a liquid flowing through a circulation flow path including a heating device at an appropriate temperature.

### Solution to Problem

According to an aspect of the present invention, a liquid heating device comprises: a circulation flow path that is connected to a branch flow path through which a first liquid supplied to an object flows; a heating device that is disposed in the circulation flow path and heats the first liquid flowing through the circulation flow path; and a cooling device that cools the first liquid flowing through the circulation flow path in a state where supply of the first liquid to the object is stopped.

### Advantageous Effects of Invention

According to an aspect of the present invention, it is possible to maintain the temperature of a liquid flowing through a circulation flow path including a heating device at an appropriate temperature.

### BRIEF DESCRIPTION OF DRAWINGS

FIG. 1 is a diagram schematically illustrating a cleaning system according to an embodiment.

FIG. 2 is a diagram schematically illustrating the cleaning system according to the embodiment.

FIG. 3 is a diagram illustrating an operation of the cleaning system according to the embodiment.

FIG. 4 is a diagram schematically illustrating the cleaning system according to the embodiment.

FIG. 5 is a diagram illustrating a relationship between a liquid temperature and an operation amount of a heating device.

FIG. 6 is a diagram illustrating a relationship between the liquid temperature and the operation amount of the heating device.

FIG. 7 is a diagram schematically illustrating the cleaning system according to an embodiment.

### DESCRIPTION OF EMBODIMENTS

Hereinafter, embodiments of the present invention will be described with reference to the drawings, but the present invention is not limited thereto. Components of the embodiments described below can be appropriately combined. Furthermore, in some cases, some components are not used.

Cleaning System

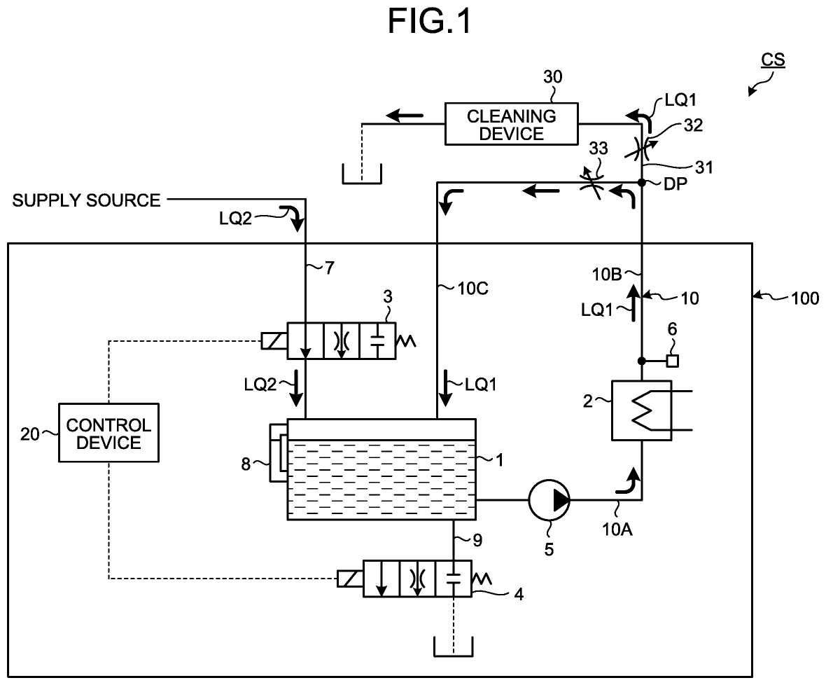

FIG. 1 is a diagram schematically illustrating a cleaning system CS according to the present embodiment. In FIG. 1, the cleaning system CS includes a liquid heating device 100 that heats a cleaning liquid LQ1 (first liquid), and a cleaning device 30 to which the liquid LQ1 heated by the liquid heating device 100 is supplied. The cleaning device 30 is an object to which the liquid LQ1 from the liquid heating device 100 is supplied. The cleaning device 30 cleans an object to be cleaned with the liquid LQ1 supplied from the liquid heating device 100. In the present embodiment, the object to be cleaned is a semiconductor wafer. The liquid LQ1 is pure water.

The liquid heating device 100 includes a circulation flow path 10 including a tank 1, a pump 5 disposed in the circulation flow path 10, a heating device 2 that heats the liquid LQ1 flowing through the circulation flow path 10, a supply flow path 7 connected to the tank 1, a discharge flow path 9 connected to the tank 1, a first valve device 3 disposed in the supply flow path 7, a second valve device 4 disposed in the discharge flow path 9, and a control device 20 that controls the liquid heating device 100.

Furthermore, the liquid heating device 100 includes a temperature sensor 6 that detects an outlet temperature indicating the temperature of the liquid LQ1 heated by the heating device 2, and a liquid level sensor 8 that detects an amount of the liquid LQ1 stored in the tank 1.

The circulation flow path 10 includes a branch portion DP connected to a branch flow path 31. The branch flow path 31 branches from the circulation flow path 10 at the branch portion DP. The liquid LQ1 supplied to the cleaning device 30 branches from the circulation flow path 10 at the branch portion DP and flows through the branch flow path 31.

The circulation flow path 10 includes the tank 1, a flow path 10A connecting the tank 1 and an inlet of the heating device 2, a flow path 10B connecting an outlet of the heating device 2 and the branch portion DP, and a flow path 10C connecting the branch portion DP and the tank 1.

The pump 5 is disposed in the flow path 10A. An operation of the pump 5 causes the liquid LQ1 to flow through the circulation flow path 10. The liquid LQ1 stored in the tank 1 is supplied to the heating device 2 via the flow path 10A, is heated by the heating device 2, and then flows through the flow path 10B. The liquid LQ1 that has flowed through the flow path 10B is returned to the tank 1 via the flow path 10C.

The liquid level sensor 8 is provided to the tank 1. The liquid level sensor 8 detects the height of a surface of the liquid LQ1 stored in the tank 1, to detect the amount of the liquid LQ1 stored in the tank 1.

The temperature sensor 6 is disposed in the flow path 10B. The temperature sensor 6 detects the outlet temperature indicating the temperature of the liquid LQ1 after being heated by the heating device 2. The temperature sensor 6 is disposed in the flow path 10B near the outlet of the heating device 2.

The heating device 2 is disposed in the circulation flow path 10. The heating device 2 includes a lamp heater such as a halogen lamp. The lamp heater heats the liquid LQ1 with radiant heat. The lamp heater can heat the liquid LQ1 while preventing contamination of the liquid LQ1.

The heating device 2 is controlled by cycle control that generates less noise. When the heating device 2 is started, a soft start is performed in order to prevent a rush current from being input to the heating device 2. The soft start refers to a starting method in which a voltage applied to the lamp heater is increased at a constant rate of change to gradually raise the temperature of the lamp heater. By the soft start, the temperature of the lamp heater gradually rises, and the input of the rush current to the lamp heater is prevented.

The heating device 2 heats the liquid LQ1 to a target temperature. The target temperature is, for example, 80° C. The heating device 2 heats the liquid LQ1 supplied from the flow path 10A and sends the heated liquid LQ1 to the flow path 10B. The liquid LQ1 heated by the heating device 2 and flowing through the flow path 10B is supplied to at least one of the flow path 10C and the branch flow path 31.

The supply flow path 7 is connected to the tank 1. The tank 1 is connected to a supply source of a liquid LQ2 (second liquid) via the supply flow path 7. The supply source is provided in a factory as equipment in the factory where the cleaning system CS is installed. The supply source sends the liquid LQ2 at a specified temperature. The specified temperature is lower than the target temperature. The specified temperature is, for example, 23° C. The liquid LQ2 sent from the supply source is supplied to the tank 1 via the supply flow path 7. The liquid LQ2 is pure water.

The first valve device 3 is disposed in the supply flow path 7. The first valve device 3 adjusts a flow rate of the liquid LQ2 supplied from the supply source to the tank 1. The first valve device 3 functions as a cooling device that cools the liquid LQ1 flowing through the circulation flow path 10.

The first valve device 3 cools the liquid LQ1 flowing through the circulation flow path 10 by sending, to the tank 1, the liquid LQ2 supplied from the supply source. The liquid LQ1 heated by the heating device 2 is supplied to the tank 1 via the flow path 10B and the flow path 10C. The temperature of the liquid LQ2 sent from the supply source is lower than the temperature of the liquid LQ1 heated by the heating device 2. Therefore, the first valve device 3 can cool the liquid LQ1 in the tank 1 by sending, to the tank 1, the liquid LQ2 sent from the supply source.

Furthermore, the first valve device 3 can adjust the temperature of the liquid LQ1 flowing through the circulation flow path 10 by adjusting the flow rate of the liquid LQ2 supplied to the tank 1. Furthermore, the first valve device 3 can stop the supply of the liquid LQ2 from the supply source to the tank 1.

The first valve device 3 includes a normal port, a throttle port, and a close port. When the supply flow path 7 and the normal port of the first valve device 3 are connected, the liquid LQ2 sent from the supply source is supplied to the tank 1 at a first flow rate. When the supply flow path 7 and the throttle port of the first valve device 3 are connected, the liquid LQ2 sent from the supply source is supplied to the tank 1 at a second flow rate smaller than the first flow rate. When the supply flow path 7 and the close port of the first valve device 3 are connected, the supply of the liquid LQ2 from the supply source to the tank 1 is stopped.

The discharge flow path 9 is connected to the tank 1. The liquid LQ1 in the tank 1 is discharged via the discharge flow path 9. The liquid LQ1 discharged from the tank 1 via the discharge flow path 9 is discarded.

The second valve device 4 is disposed in the discharge flow path 9. The second valve device 4 adjusts a flow rate of the liquid LQ1 discharged from the tank 1.

The second valve device 4 includes a normal port, a throttle port, and a close port. When the discharge flow path 9 and the normal port of the second valve device 4 are connected, the liquid LQ1 in the tank 1 is discharged from the tank 1 at a first flow rate. When the discharge flow path 9 and the throttle port of the second valve device 4 are connected, the liquid LQ1 in the tank 1 is discharged from the tank 1 at a second flow rate smaller than the first flow rate. When the discharge flow path 9 and the close port of the second valve device 4 are connected, the discharge of the liquid LQ1 from the tank 1 is stopped.

A flow rate adjustment valve 32 is disposed in the branch flow path 31. The flow rate adjustment valve 32 is a variable flow rate adjustment valve that can adjust a flow rate of the liquid LQ1 flowing through the branch flow path 31. The flow rate adjustment valve 32 adjusts the flow rate of the liquid LQ1 supplied to the cleaning device 30 via the branch flow path 31. When the flow rate adjustment valve 32 is opened, the liquid LQ1 is supplied to the cleaning device 30. When the flow rate adjustment valve 32 is closed, the supply of the liquid LQ1 to the cleaning device 30 is stopped.

A flow rate adjustment valve 33 is disposed in the flow path 10C. The flow rate adjustment valve 33 is a variable flow rate adjustment valve that can adjust a flow rate of the liquid LQ1 flowing through the circulation flow path 10. The flow rate adjustment valve 33 adjusts the flow rate of the liquid LQ1 supplied to the tank 1 via the flow path 10C. When the flow rate adjustment valve 33 is opened, the liquid LQ1 is supplied to the tank 1, and the liquid circulates in the circulation flow path 10. When the flow rate adjustment valve 33 is closed, the supply of the liquid LQ1 to the tank 1 is stopped.

At least a part of the liquid LQ1 flowing through the circulation flow path 10 is supplied to the cleaning device 30 based on an opening degree of the flow rate adjustment valve 32 and an opening degree of the flow rate adjustment valve 33. When the flow rate adjustment valve 32 is opened, at least a part of the liquid LQ1 flowing through the circulation flow path 10 branches into the branch flow path 31 at the branch portion DP, and is supplied to the cleaning device 30.

Furthermore, based on the opening degree of the flow rate adjustment valve 32 and the opening degree of the flow rate adjustment valve 33, the flow rate of the liquid LQ1 supplied from the branch portion DP to the cleaning device 30 and the flow rate of the liquid LQ1 supplied to the tank 1 from the branch portion DP are adjusted.

The flow rate adjustment valve 32 adjusts a flow rate of the liquid LQ1 based on a required flow rate of the cleaning device 30. The required flow rate refers to a flow rate of the liquid LQ1 required by the cleaning device 30. When a flow rate of the liquid LQ1 at the branch portion DP of the circulation flow path 10 is larger than the required flow rate, the surplus liquid LQ1 is returned to the tank 1 via the flow path 10C, and circulates in the circulation flow path 10.

The control device 20 outputs operation commands for controlling the liquid heating device 100. The control device 20 outputs operation commands for controlling at least the first valve device 3 and the second valve device 4. A solenoid is connected to each of the first valve device 3 and the second valve device 4. The control device 20 can output an operation command to each solenoid to operate each of the first valve device 3 and the second valve device 4. The first valve device 3 and the second valve device 4 operate based on the operation commands output from the control device 20.

FIG. 1 illustrates a state where the supply flow path 7 and the normal port of the first valve device 3 are connected, and the discharge flow path 9 and the close port of the second valve device 4 are connected. Furthermore, a state is illustrated where each of the flow rate adjustment valve 32 and the flow rate adjustment valve 32 is opened, a part of the liquid LQ1 flowing through the circulation flow path 10 flows through the branch flow path 31 and is supplied to the cleaning device 30, and the surplus liquid LQ1 is returned to the tank 1 via the flow path 10C and circulates in the circulation flow path 10.

The cleaning device 30 cleans the semiconductor wafer with the liquid LQ1 heated by the heating device 2 and supplied via the branch flow path 31. The liquid LQ1 used for cleaning is discarded.

Operation

Next, an operation of the cleaning system CS according to the present embodiment will be described.

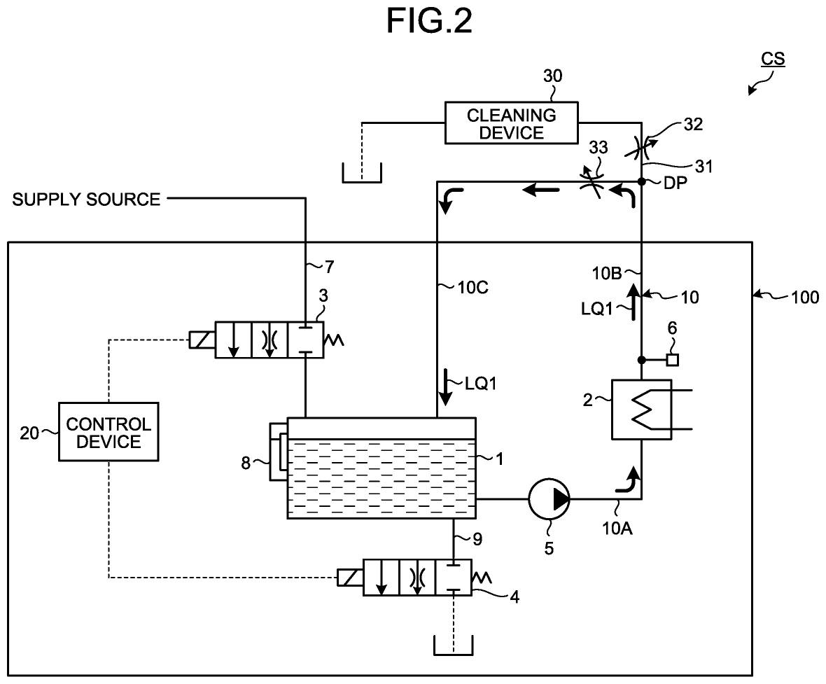

An operation of starting the liquid heating device 100 in a state where the liquid LQ1 is not stored in the tank 1 will be described. FIG. 2 is a diagram schematically illustrating the cleaning system CS according to the present embodiment.

When the liquid heating device 100 is started in the state where the liquid LQ1 is not stored in the tank 1, the control device 20 connects the supply flow path 7 and the normal port of the first valve device 3. As a result, the liquid LQ2 sent from the supply source is supplied to the tank 1 via the supply flow path 7. Furthermore, when the liquid LQ2 sent from the supply source is supplied to the tank 1 via the supply flow path 7, the control device 20 connects the supply flow path 7 and the close port of the second valve device 4.

When the control device 20 determines that the liquid LQ1 stored in the tank 1 has reached an upper limit based on detection data of the liquid level sensor 8, the control device 20 connects the supply flow path 7 and the close port of the first valve device 3. As a result, the supply of the liquid LQ2 from the supply source to the tank 1 is stopped.

The control device 20 starts the pump 5 with the flow rate adjustment valve 32 closed and the flow rate adjustment valve 33 opened. As a result, as illustrated in FIG. 2, the liquid LQ1 circulates in the circulation flow path 10 in a state where the supply of the liquid LQ1 to the cleaning device 30 is stopped.

After the circulation of the liquid LQ1 in the circulation flow path 10 is started, the control device 20 starts the heating device 2. The control device 20 controls the heating device 2 based on detection data of the temperature sensor 6 so that an outlet temperature of the liquid LQ1 heated by the heating device 2 reaches a target temperature.

Next, an operation of supplying the liquid LQ1 heated by the heating device 2 to the cleaning device 30 will be described. After the outlet temperature of the liquid LQ1 reaches the target temperature, the flow rate adjustment valve 32 is opened. As a result, as illustrated in FIG. 1, at least a part of the liquid LQ1 heated by the heating device 2 and circulating in the circulation flow path 10 is supplied to the cleaning device 30 via the branch flow path 31. The liquid used for cleaning in the cleaning device 30 is discarded.

Due to the supply of the liquid LQ1 to the cleaning device 30 and the discard of the liquid LQ1 in the cleaning device 30, an amount of the liquid LQ1 circulating in the circulation flow path 10 decreases, and an amount of the liquid LQ1 stored in the tank 1 decreases.

When the control device 20 determines that the liquid LQ1 stored in the tank 1 is smaller than a lower limit based on the detection data of the liquid level sensor 8, the control device 20 connects the supply flow path 7 and the normal port of the first valve device 3. As a result, the liquid LQ2 sent from the supply source is supplied to the tank 1 via the supply flow path 7. Since the circulation flow path 10 including the tank 1 is replenished with the liquid LQ2 from the supply source, the amount of the liquid LQ1 stored in the tank 1 is increased.

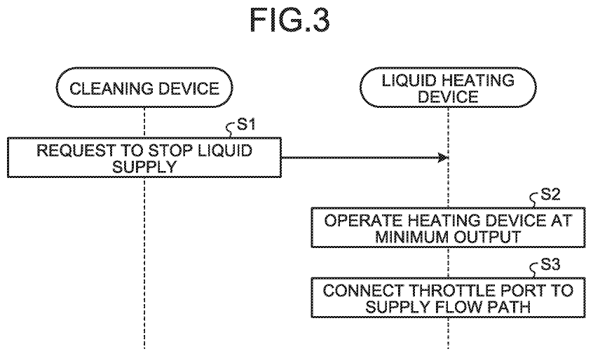

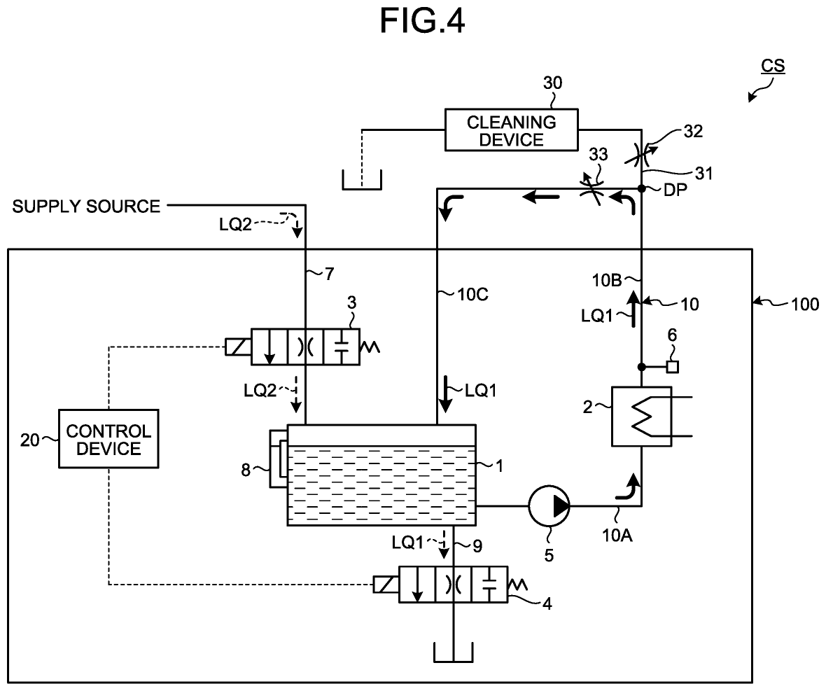

Next, an operation when the supply of the liquid LQ1 to the cleaning device 30 is stopped will be described. FIG. 3 is a diagram illustrating the operation of the cleaning system CS according to the present embodiment. FIG. 4 is a diagram schematically illustrating the cleaning system CS according to the present embodiment.

When a cleaning process by the cleaning device 30 is not performed, the required flow rate of the cleaning device 30 becomes zero. When the cleaning process by the cleaning device 30 is not performed, the flow rate adjustment valve 32 is closed. The cleaning device 30 outputs a request signal requesting a stop of the supply of the liquid LQ1 to the control device 20 of the liquid heating device 100 (Step S1).

When the flow rate adjustment valve 32 is closed and the supply of the liquid LQ1 to the cleaning device 30 is stopped, the liquid LQ1 circulates in the circulation flow path 10.

Even in the state where the supply of the liquid LQ1 to the cleaning device 30 is stopped, an operation of the heating device 2 is maintained. Once the operation of the heating device 2 is stopped, it takes time to raise the temperature to a target temperature when the heating device 2 is restarted, which results in unnecessary energy consumption. In addition, when the heating device 2 is restarted, the above-described soft start is required. During a period in which the soft start is being performed, disturbance due to the soft start enters, and an uncontrolled state occurs. Therefore, in the present embodiment, even in the state where the supply of the liquid LQ1 to the cleaning device 30 is stopped and the liquid LQ1 is circulating in the circulation flow path 10, the heating device 2 is not stopped, and the operation of the heating device 2 is maintained.

When the operation of the heating device 2 is maintained in the state where the supply of the liquid LQ1 to the cleaning device 30 is stopped, the control device 20 operates the heating device 2 at a minimum output (Step S2). As a result, it is possible to reduce energy consumption while preventing lowering in the temperature in the heating device 2.

If the liquid LQ1 continues to circulate in the circulation flow path 10 in the state where the operation of the heating device 2 is maintained, the temperature of the liquid LQ1 may excessively rise.

Therefore, the control device 20 cools the liquid LQ1 flowing through the circulation flow path 10 by controlling the first valve device 3 to supply, to the tank 1, the liquid LQ2 from the supply source in the state where the supply of the liquid LQ1 to the cleaning device 30 is stopped.

As illustrated in FIG. 4, the control device 20 controls the first valve device 3 to connect the supply flow path 7 and the throttle port of the first valve device 3. As a result, since the liquid LQ2 at a specified temperature is supplied to the tank 1, the temperature of the liquid LQ1 flowing through the circulation flow path 10 lowers. Furthermore, by supplying, to the tank 1 via the first valve device 3, the liquid LQ2 sent from the supply source, the liquid LQ1 flowing through the circulation flow path 10 is cooled in the state where the heating device 2 is operating at the minimum output.

Furthermore, as illustrated in FIG. 4, the control device 20 controls the second valve device 4 to connect the discharge flow path 9 and the throttle port of the second valve device 4. As a result, even when the liquid LQ2 is supplied to the circulation flow path 10 including the tank 1 via the supply flow path 7, the liquid LQ1 is prevented from being overflowed from the tank 1. In the present embodiment, a flow rate of the liquid LQ2 supplied to the tank 1 via the throttle port of the first valve device 3 is the same as a flow rate of the liquid LQ1 discharged from the tank 1 via the throttle port of the second valve device 4.

Note that, after the supply of the liquid LQ1 to the cleaning device 30 is stopped, the control device 20 may maintain a state where the supply flow path 7 and the close port of the first valve device 3 are connected. After the supply of the liquid LQ1 to the cleaning device 30 is stopped, when the control device 20 determines that the temperature of the liquid LQ1 flowing through the circulation flow path 10 has exceeded a predetermined threshold based on detection data of the temperature sensor 6, the control device 20 may change the state where the supply flow path 7 and the close port of the first valve device 3 are connected to a state where the supply flow path 7 and the throttle port of the first valve device 3 are connected.

Furthermore, after the supply of the liquid LQ1 to the cleaning device 30 is stopped, the control device 20 may alternately change, from one to the other, the state where the supply flow path 7 and the close port of the first valve device 3 are connected and the state where the supply flow path 7 and the throttle port of the first valve device 3 are connected. That is, the control device 20 may supply, to the tank 1, the liquid LQ2 from the supply source intermittently.

Flow Rate of Liquid

Next, a flow rate Qs of the liquid LQ2 supplied to the tank 1 via the first valve device 3 in a state where the supply of the liquid LQ1 to the cleaning device 30 is stopped will be described.

A circulation flow rate of the liquid LQ1 flowing through the circulation flow path 10 is represented by Qc L/min, a flow rate of the liquid LQ2 passing through the throttle port of the first valve device 3 and a flow rate of the liquid LQ1 passing through the throttle port of the second valve device 4 are represented by Qs L/min, a target temperature of the liquid LQ1 is represented by SV ° C., the temperature of the liquid LQ2 supplied from the supply source is represented by Tw ° C., a minimum output of heating device 2 is represented by Pmin kW, a natural heat radiation amount in the circulation flow path 10 is represented by ΔT ° C., and a calorie conversion factor is represented by K.

The minimum output Pmin is a value determined based on performance (specifications) of the heating device 2. The natural heat radiation amount ΔT is a natural heat radiation amount in the flow path 10B and the flow path 10C when the heating device 2 operates at the minimum output Pmin and the liquid LQ1 at the target temperature SV flows through the circulation flow path 10. The calorie conversion factor K is a characteristic value of a liquid.

An inlet temperature Tin_m of the liquid LQ1 at the inlet of the heating device 2 when the heating device 2 is operating at the minimum output Pmin is derived from the following formula (1).

$${T}_{{in}_{-} m} \leq S V - \frac{K \times {P}_{min}}{{Q}_{c}} \qquad ( 1 )$$

In the tank 1, the liquid LQ2 supplied from the supply source and the liquid LQ1 heated by the heating device 2 are mixed. Therefore, the inlet temperature Tin_m of the liquid LQ1 after the liquid LQ2 is mixed is derived from the following formula (2).

$${T}_{{in}_{-} m} \geq \frac{( S V - Δ T ) \times {Q}_{c} + {T}_{w} \times {Q}_{s}}{{Q}_{c} + {Q}_{s}} \qquad ( 2 )$$

Assuming the worst condition where there is no natural heat radiation amount ΔT (ΔT=0), the inlet temperature Tin_m is derived from the following formula (3).

$${T}_{i {n}_{-} m} \geq \frac{S V \times {Q}_{c} + {T}_{w} \times {Q}_{s}}{{Q}_{c} + {Q}_{s}} \qquad ( 3 )$$

As described above, the required flow rate Qs of the liquid LQ2 supplied from the supply source to the tank 1 is derived from the following formula (4).

$${Q}_{s} > \frac{( S V - {T}_{i {n}_{-} m} ) \times {Q}_{c}}{( {T}_{i {n}_{-} m} - {T}_{w} )} \qquad ( 4 )$$

By disposing, in the supply flow path 7, the first valve device 3 including the throttle port satisfying a condition of the formula (4), the temperature of the liquid LQ1 circulating in the circulation flow path 10 is prevented from rising excessively even when the liquid LQ1 is circulated in the circulation flow path 10 in the state where the operation of the heating device 2 is maintained.

Effect

As described above, according to the present embodiment, when the supply of the liquid LQ1 to the cleaning device 30 is stopped, the liquid LQ1 flowing through the circulation flow path 10 is cooled. As a result, the temperature of the liquid LQ1 circulating in the circulation flow path 10 is prevented from excessively rising in the state where the operation of the heating device 2 is maintained.

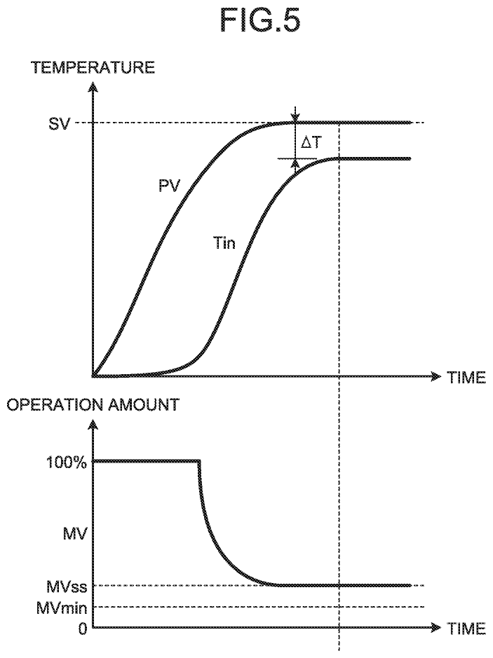

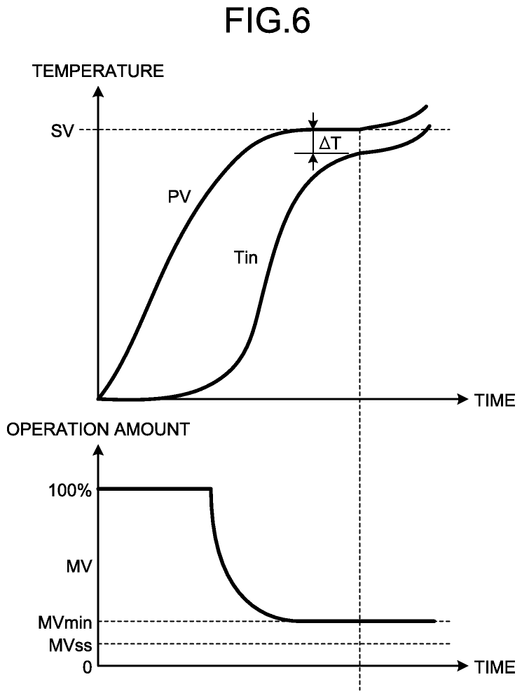

FIGS. 5 and 6 illustrate a relationship among an inlet temperature Tin of the liquid LQ1 at the inlet of the heating device 2 when the heating device 2 is operating, an outlet temperature PV of the liquid LQ1 at the outlet of the heating device 2, and an operation amount MV of the heating device 2.

As illustrated in FIG. 5, when the heating device 2 continues to heat the liquid LQ1 in the state where the supply of the liquid LQ1 to the cleaning device 30 is stopped, a difference between the inlet temperature Tin and the outlet temperature PV gradually decreases. When the outlet temperature PV reaches the target temperature SV, the inlet temperature Tin enters a steady state at a temperature lower by T ° C. than the outlet temperature PV.

At this time, an operation amount MVss of the heating device 2 is larger than an operation amount MVmin corresponding to the minimum output of the heating device 2. ΔT is a natural heat radiation amount of the circulation flow path 10, and it is possible to be balanced at the target temperature SV if the following formula is satisfied in the steady state:

natural heat radiation amount>minimum output of heating device 2 (5).

However, as illustrated in FIG. 6, when the operation amount MVss of the heating device 2 that can be balanced with the natural heat radiation amount ΔT is smaller than the operation amount MVmin corresponding to the minimum output of the heating device 2, that is, when the following formula is satisfied:

natural heat radiation amount<minimum output of heating device 2 (6),

the liquid LQ1 cannot be completely cooled even when the temperature of the liquid LQ1 exceeds the target temperature SV, since a heating capacity of the heating device 2 is superior to a natural heat radiation capacity of the circulation flow path 10. Thus, the temperature of the liquid LQ1 cannot be controlled.

In addition, when the heating device 2 is stopped, as described above, a soft start is required at the time of restarting the heating, and during the soft start, disturbance due to the soft start enters and an uncontrolled state occurs.

In the present embodiment, when the supply of the liquid LQ1 to the cleaning device 30 is stopped, and the liquid LQ1 is circulated in the circulation flow path 10 in the state where the heating device 2 is operating, the liquid LQ2 from the supply source is injected into the circulation flow path 10. As a result, a state where the following condition is satisfied is generated:

natural heat radiation amount+cooling amount by liquid supply>minimum output of heating device 2 (7).

Therefore, occurrence of a state where the temperature of the liquid LQ1 cannot be controlled is prevented.

### Another Embodiment

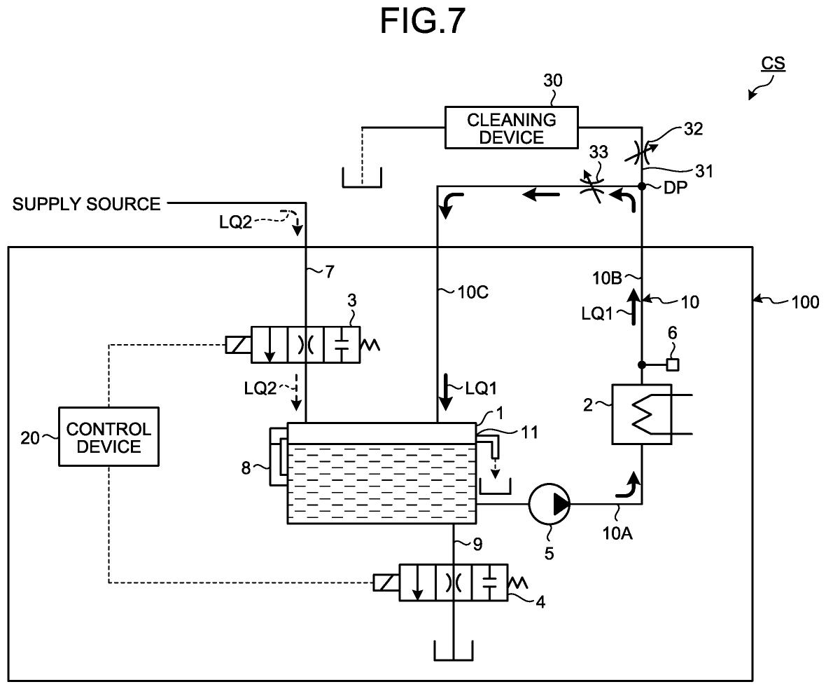

FIG. 7 is a diagram schematically illustrating a cleaning system CS according to another embodiment. In the example illustrated in FIG. 7, a second valve device 4 includes a normal port and a close port, and does not include a throttle port. A tank 1 includes a discharge port 11 provided at an upper part of the tank 1. When the height of a surface of a liquid LQ1 stored in the tank 1 becomes equal to or higher than a specified height, at least a part of the liquid LQ1 stored in the tank 1 flows out of the tank 1 from the discharge port 11.

When the liquid LQ1 flowing through a circulation flow path 10 is cooled, a liquid LQ2 from a supply source is supplied to the tank 1 via a first valve device 3. By supplying, to the tank 1 via the first valve device 3, the liquid LQ2 sent from the supply source, the liquid LQ1 flowing through the circulation flow path 10 is cooled in the state where a heating device 2 is operating at a minimum output.

When the liquid LQ2 is supplied from the supply source to the tank 1 and an amount of the liquid LQ1 stored in the tank 1 increases, at least a part of the liquid LQ1 stored in the tank 1 is discharged from the discharge port 11. In the present embodiment, a flow rate of the liquid LQ2 supplied to the tank 1 via a throttle port of the first valve device 3 is the same as a flow rate of the liquid LQ1 discharged from the tank 1 via the discharge port 11.

Note that, in the above embodiment, it is assumed that the liquid LQ2 from the supply source is supplied to the tank 1 via the first valve device 3 in a state where the supply of the liquid LQ1 to the cleaning device 30 is stopped. The liquid LQ2 from the supply source may be supplied to the tank 1 via the first valve device 3 in a state where at least a part of the liquid LQ1 flowing through the circulation flow path 10 is supplied to the cleaning device 30. For example, when at least a part of the liquid LQ1 flowing through the circulation flow path 10 is being supplied to the cleaning device 30, and the temperature of the liquid LQ1 flowing through the circulation flow path 10 rises, in a state where the supply flow path 7 and a close port of the first valve device 3 are connected, the control device 20 may connect the supply flow path 7 and the throttle port of the first valve device 3 based on detection data of a temperature sensor 6 so that the temperature of the liquid LQ1 flowing through the circulation flow path 10 lowers. As a result, the first valve device 3 can cool the liquid LQ1 in the circulation flow path 10 in the state where at least a part of the liquid LQ1 flowing through the circulation flow path 10 is supplied to the cleaning device 30.

Note that, in the above embodiment, it is assumed that the cooling device includes the first valve device 3. The cooling device is not limited to the first valve device 3 as long as the liquid LQ1 flowing through the circulation flow path 10 can be cooled in the state where the supply of the liquid LQ1 to the cleaning device 30 is stopped. For example, when the circulation flow path 10 is formed by a pipe member, the cooling device may be a Peltier element connected to a surface of the pipe member.

In the above embodiment, the heating device 2 includes the lamp heater. The lamp heater can efficiently heat the liquid LQ1 while preventing contamination of the liquid LQ1. Note that the heating device 2 does not have to be the lamp heater.

In the above embodiment, the liquid LQ1 is water. Since the liquid is water, it is possible to clean the semiconductor wafer. Note that the liquid LQ1 does not have to be water, but may be a chemical solution used in a semiconductor manufacturing process.

In the above embodiment, an object to be cleaned does not have to be a semiconductor wafer, but may be, for example, a glass substrate.

In the above embodiment, an object to which the liquid is supplied does not have to be the cleaning device, but may be, for example, an exposure device.

### REFERENCE SIGNS LIST

1 Tank
2 Heating device
3 First valve device (Cooling device)
4 Second valve device
6 Temperature sensor
7 Supply flow path
8 Liquid level sensor
9 Discharge flow path
10 Circulation flow path
10A Flow path
10B Flow path
10C Flow path
11 Discharge port
30 Cleaning device
31 Branch flow path
32 Flow rate adjustment valve
33 Flow rate adjustment valve
20 Control device
100 Liquid heating device
CS Cleaning system
DP Branch portion
LQ1 Liquid (First liquid)
LQ2 Liquid (Second liquid)

1. A liquid heating device comprising:
a circulation flow path that is connected to a branch flow path through which a first liquid supplied to an object flows;
a heating device that is disposed in the circulation flow path and heats the first liquid flowing through the circulation flow path; and
a cooling device that cools the first liquid flowing through the circulation flow path in a state where supply of the first liquid to the object is stopped.

2. The liquid heating device according to claim 1, wherein
the circulation flow path includes a tank, and
the cooling device includes a first valve device that adjusts a flow rate of a second liquid supplied to the tank from a supply source.

3. The liquid heating device according to claim 2, further comprising
a second valve device that adjusts a flow rate of the first liquid discharged from the tank.

4. The liquid heating device according to claim 2, further comprising
a discharge port provided at an upper part of the tank and through which at least a part of the first liquid stored in the tank flows out.

5. The liquid heating device according to claim 1, wherein
the cooling device cools the first liquid in a state where the heating device is operating.

6. The liquid heating device according to claim 5, wherein
the heating device includes a lamp heater.

7. The liquid heating device according to claim 1, wherein
the cooling device cools the first liquid in a state where the first liquid is supplied to the object.

8. The liquid heating device according to claim 1, wherein
the first liquid is pure water.

9. A cleaning system comprising
the liquid heating device according to claim 1, wherein
the object includes a cleaning device, and cleans an object to be cleaned with the first liquid supplied from the liquid heating device.
